(19) United States
(12) Patent Application Publication
(10) Pub. No.: US 2026/0182443 A1
(43) Pub. Date: Jun. 25, 2026

(54) CHIP SCALE PACKAGING WITH DOUBLE-SIDED PLATING FOR EMBEDDED DEVICES

(71) Applicant: SEMICONDUCTOR COMPONENTS INDUSTRIES, LLC, Scottsdale, AZ (US)

(72) Inventor: Ankit Bhushan SHARMA, Erding (DE)

(73) Assignee: SEMICONDUCTOR COMPONENTS INDUSTRIES, LLC, Scottsdale, AZ (US)

(21) Appl. No.: 18/989,615

(22) Filed: Dec. 20, 2024

(51) Int. Cl. H01L 23/31; H01L 21/302; H01L 21/56; H01L 21/683; H01L 23/00

(52) U.S. Cl. CPC H10W 74/129; H10P 50/00; H10P 72/74; H10W 42/121; H10W 74/016; H10W 74/141; H10P 72/7416; H10W 72/952

(57) ABSTRACT

A semiconductor device package includes a semiconductor device having a first side and a second side opposed to the first side. A first metallization layer is disposed on the first side, and a first metal layer formed on the first metallization layer. The first metal layer includes a first pattern defined by a first space, the first space including a first non-conducting material formed on the first metallization layer. A second metallization layer is disposed on the second side, and a second metal layer is formed on the second metallization layer. A second pattern may be formed in the second metal layer and may be based on the first pattern to provide mechanical stress relief for the semiconductor device.

### TECHNICAL FIELD

This description relates to semiconductor device packaging.

### BACKGROUND

Semiconductor device packaging generally involves encasing one or more semiconductor devices in a protective housing that provides for electrical connections, heat dissipation, mechanical support, and/or electrical isolation. Many different types of semiconductor device packaging exist, providing varying degrees of packaging parameters. Such packaging parameters may include, but are not limited to, performance (e.g., speed or power handling) parameters, cost parameters, and/or size parameters.

Semiconductor device packages, including embedded device packages, are often produced through a partnership between the manufacturers of the semiconductor devices and providers of substrates and other packaging elements, e.g., printed circuit boards (PCBs). For example, the semiconductor device manufacturers may generally design and fabricate semiconductor dies, including providing detailed specifications about the layout, electrical requirements, and thermal characteristics of the die(s). PCB providers, for example, may ensure that relevant PCB designs accommodate related semiconductor dies, including designing layers for routing, power delivery, and thermal management. For embedded device packages, in which semiconductor dies are embedded directly into PCB layers, the PCB provider may be responsible for ensuring that the embedding process does not damage the dies and that electrical connections are reliable.

### SUMMARY

According to one general aspect, a semiconductor device package includes a semiconductor device having a first side and a second side opposed to the first side, a first metallization layer disposed on the first side, and a first metal layer formed on the first metallization layer, the first metal layer including a first pattern defined by a first space, the first space including a first non-conducting material formed on the first metallization layer. The semiconductor device package further includes a second metallization layer disposed on the second side, and a second metal layer formed on the second metallization layer.

According to another general aspect, a package for an embedded semiconductor device includes a substrate and a semiconductor device disposed on the substrate, the semiconductor device having a first side and a second side opposed to the first side. The package further includes a first metallization layer disposed on the first side, and a first metal layer formed on the first metallization layer and including a first stress-relief pattern defined by a first metal layer portion and a second metal layer portion with a first space therebetween, the first space including a first non-conducting material formed on the first metallization layer. The package further includes a second metallization layer disposed on the second side, a second metal layer formed on the second metallization layer, and an encapsulant fixing the semiconductor device, the first metal layer, and the second metal layer to the substrate.

According to another general aspect, a method of forming a semiconductor device package includes forming a first metallization layer on a first side of a semiconductor device, forming a second metallization layer on a second side of the semiconductor device that is opposed to the first side, and forming a first metal layer on the first metallization layer, the first metal layer including a first pattern defined by a first space. The method further includes forming a first non-conducting material in the first space and on the first metallization layer, and forming a second metal layer on the second metallization layer.

The details of one or more implementations are set forth in the accompanying drawings and the description below. Other features will be apparent from the description and drawings, and from the claims.

### BRIEF DESCRIPTION OF THE DRAWINGS

FIG. 1A is a side view of a semiconductor device with double-sided, patterned plating.

FIG. 1B is a top view of a semiconductor device that may use double-sided, patterned plating.

FIG. 1C is a bottom view of a semiconductor device with double-sided, patterned plating.

FIG. 2 is a side view of a multi-device semiconductor device with double-sided, patterned plating.

FIG. 3 is a side view of a first example semiconductor device package that includes the semiconductor device of FIG. 1A.

FIG. 4 is a side view of a second example semiconductor device package that includes the semiconductor device of FIG. 1A.

FIG. 5A illustrates an example first operation for forming a semiconductor device with double-sided, patterned plating.

FIG. 5B illustrates an example second operation for forming a semiconductor device with double-sided, patterned plating.

FIG. 5C illustrates an example third operation for forming a semiconductor device with double-sided, patterned plating.

FIG. 6A illustrates an example fourth operation for forming a semiconductor device with double-sided, patterned plating.

FIG. 6B illustrates an example fifth operation for forming a semiconductor device with double-sided, patterned plating.

FIG. 6C illustrates an example sixth operation for forming a semiconductor device with double-sided, patterned plating.

FIG. 7A illustrates an example alternate fourth operation for forming a semiconductor device with double-sided, patterned plating.

FIG. 7B illustrates an example alternate fifth operation for forming a semiconductor device with double-sided, patterned plating.

FIG. 7C illustrates an example alternate sixth operation for forming a semiconductor device with double-sided, patterned plating and sidewall protection.

FIG. 8 illustrates example grinding and dicing of a result of the alternate sixth operation of FIG. 7C, including a single chip package with sidewall protection and a multi-chip package with sidewall protection.

FIG. 9A illustrates an example alternate fourth operation for forming a semiconductor device with double-sided, patterned plating.

FIG. 9B illustrates an example alternate fifth operation for forming a semiconductor device with double-sided, patterned plating.

FIG. 9C illustrates an example alternate sixth operation for forming a semiconductor device with double-sided, patterned plating.

FIG. 10A illustrates an example eighth operation for forming a semiconductor device with double-sided plating and sidewall protection, with fanout layers.

FIG. 10B illustrates an example ninth operation for forming a semiconductor device with double-sided plating and sidewall protection, with fanout layers.

FIG. 10C illustrates an example tenth operation for forming a semiconductor device with double-sided plating and sidewall protection, with fanout layers.

FIG. 11 is a flowchart illustrating example operations for forming semiconductor devices of FIGS. 1A-10C.

FIG. 12 is an example multi-chip semiconductor device with double-sided plating and sidewall protection, with fanout layers.

FIG. 13 is a first example semiconductor device package for a semiconductor device with double-sided plating and sidewall protection, with fanout layers.

FIG. 14 is a second example semiconductor device package for a semiconductor device with double-sided plating and sidewall protection, with fanout layers.

FIG. 15 is a third example semiconductor device package for a semiconductor device with double-sided plating and sidewall protection, with fanout layers.

### DETAILED DESCRIPTION

Described techniques and embodiments provide improved semiconductor device packaging, including facilitating assembly, increasing safety margins, and enhancing encapsulation. For example, semiconductor dies may be manufactured with patterned metal plating on one or both sides of each semiconductor die. The patterned metal plating reduces warpage and breakage during, e.g., subsequent die handling and via formation.

As referenced above, packaging providers and semiconductor die makers often have a symbiotic relationship, with each party relying on the other's expertise for the success of final products, such as embedded semiconductor device packages. For example, semiconductor die makers depend on package providers for effective integration and manufacturing capabilities, while package providers need detailed semiconductor specifications to design boards that meet performance, size, and cost requirements. This partnership has led to developments in fields such as, e.g., mobile devices, automotive electronics, IoT, high-performance computing, and other technology areas in which embedded technologies are becoming increasingly prevalent.

In some cases, however, the package providers, e.g., substrate providers or PCB providers, may not have the tools necessary to process received semiconductor dies in a reliable, efficient, cost-effective manner. For example, manufactured semiconductor dies are often very thin and prone to warpage or breakage. Semiconductor manufacturers may possess best-available tools to handle such dies, although even such semiconductor manufacturers may experience some level of die damage. Package providers, however, may be unlikely to possess such die handling tools, and may be forced to use tools that are prone to cause damage to semiconductor dies during embedding processes.

It is possible to reinforce a structure of semiconductor dies using various known techniques, including, e.g., providing a reinforcing metal layer on a semiconductor die. Such a layer may reduce damage during tool handling at the package provider, but, if too thick, may be likely to result in warping of the associated die due to mechanical stress imposed on the die.

Moreover, such metal layers may need to be drilled through to form vias to be used in providing external connections for the semiconductor die. For example, suitable lasers may be used to provide such drilling. In many cases, however, such lasers or other drilling tools may be prone to over-drilling the metal layers, resulting in an overshoot that damages the underlying die. It may be possible to reduce the frequency of such damage by using thicker metal layers, but such thicker metal layers, as referenced above, exert more mechanical stress on the die and are therefore more likely to result in warping. It may also be possible to reduce the frequency of such damage by using slower and/or more expensive lasers or other drilling techniques, but such techniques add time and cost to the package provider operations.

Described techniques, in contrast, provide patterned metal layer(s) on semiconductor dies that can be formed with a desired level(s) of thickness, without causing warpage of the associated die. With such thicker metal layers, the danger of drilling overshoot is reduced, and faster/more inexpensive drilling techniques may be used.

For example, double-sided patterned metal layers may be formed on both a top and bottom of a semiconductor die. Such double-sided patterned metal layers compensate mechanical stress caused by one another, so that a net mechanical stress imposed on the die is reduced, and a likelihood of warpage is correspondingly reduced.

For example, a patterning of a top-side metal layer may be dictated or influenced by a pattern(s) of metal contacts formed on the top side of the semiconductor die (e.g., a source contact and a gate contact). In some implementations, a bottom-side metal layer may then be provided over an entirety or almost an entirety of the bottom side of the semiconductor die.

In other implementations, the bottom-side metal layer may be patterned. For example, such a patterning of a bottom-side metal layer may be selected to reduce or compensate for mechanical stress and warpage that would otherwise be caused by the top-side metal layer.

In some examples, a simulation tool may be used to determine the top-side and/or bottom-side metal patterning. For example, the top-side patterning may be dictated at least partially by a layout of top-side contact pads of the semiconductor die, and may be input to the simulation tool with a request for corresponding bottom-side patterning that minimizes warping of the die. In other examples, both the top-side and the bottom-side patterning may be output based on various factors, including, e.g., the top-side contacts, a thickness or other parameter of the die, a thickness of the patterned metal layers, and/or a degree of permissible warpage. Put another way, warpage may be used as a simulation parameter to be minimized when simulating potential top-side and/or bottom-side patterning.

In some implementations, the patterned metals may be provided using various masking and plating techniques. For example, masks may be provided on the top side and/or bottom side of a semiconductor die to define a desired pattern(s). Then, copper plating may be provided simultaneously, in a single process, on both a top side and bottom side of the semiconductor die.

In some implementations, molding may be provided within any grooves or other spaces defined by the metal patterns, e.g., for further stability and/or for electrical isolation. Grinding may then be performed to reduce a thickness of the patterned metal and the molding, so as to achieve a desired thickness of the metal plating. Such grinding may also serve to ensure a uniform and consistent height of the metal and molding across a surface(s) of the semiconductor die.

In some implementations, embedded sidewalls may be provided at one or more sides of the semiconductor die. Such sidewalls may provide enhanced stability, and may cause the semiconductor die to be less likely to experience damage when being embedded, e.g., into a PCB or other substrate.

Moreover, some embedded packaging techniques are prone to difficulties resulting from conductive anodic filaments (CAFs), which refer to, e.g., migration of copper or other metal ions through non-conductive materials under the influence of an electric field. For example, prepreg materials used in embedded packaging techniques are prone to CAF growth. Such CAF growth may result in, e.g., short circuits or other failure mechanisms. The addition of described epoxy mold compound (EMC) sidewalls provides protection against CAF growth and thereby results in increased reliability and stability of embedded packages.

In some implementations, fanout layers may be provided in conjunction with the patterned metal layers. Such fanout layers may serve, e.g., to facilitate or enhance external connections to the semiconductor die.

Using described techniques, a metal thickness on a top side of a semiconductor die may be increased to be in the range of, e.g., 10 microns-200 microns, or more. As a result of using described techniques, warpage or other damage to semiconductor devices may be reduced, and vias for the semiconductor devices may be formed quickly, inexpensively, and reliably. Thus, semiconductor manufacturers may experience a higher yield of embedded packages received from package providers, and package providers may experience a more streamlined and efficient process(es) for providing the embedded packages.

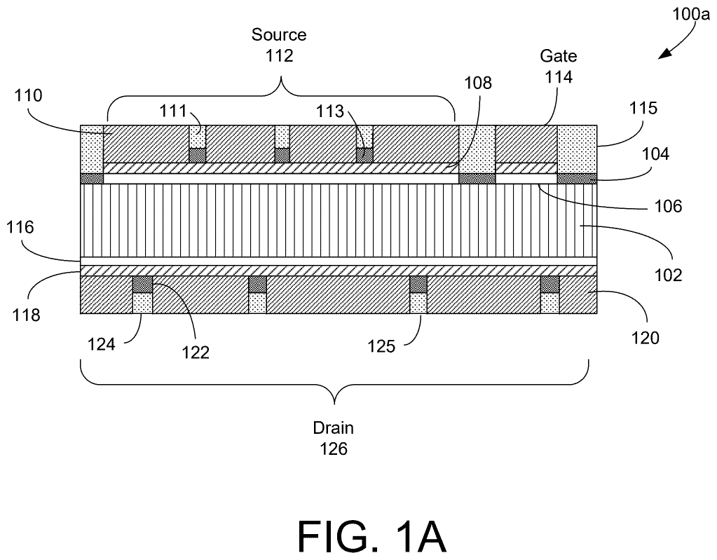

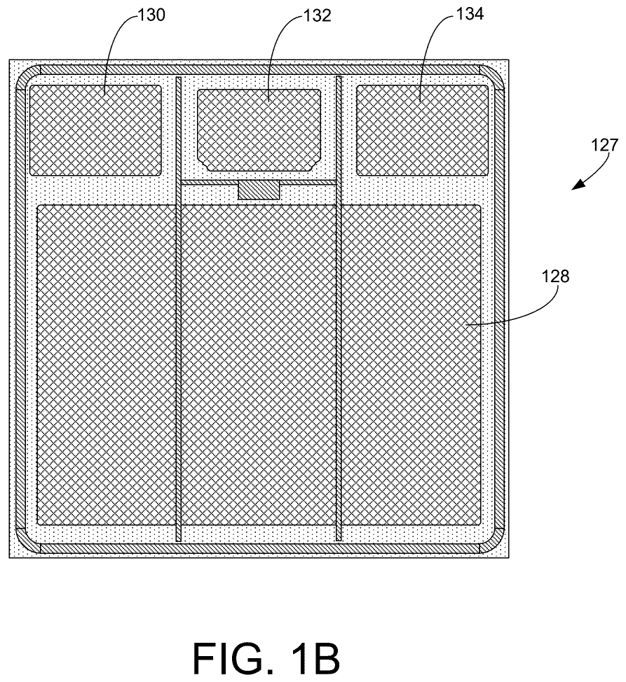

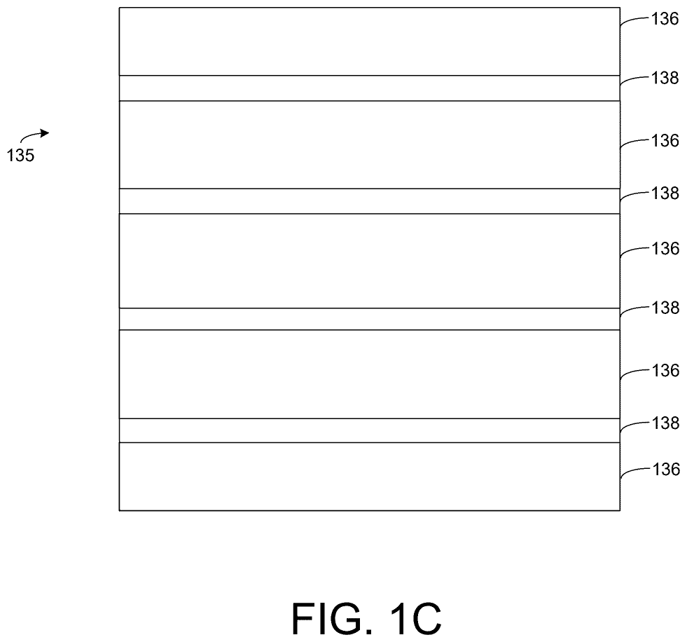

FIG. 1A is a side view of a semiconductor device 100a with double-sided plating. In the example of FIG. 1A, a semiconductor die 102 is illustrated as having a first or top side in an upper portion of the figure, and a second or bottom side on a lower portion of the figure. On the top side of the semiconductor die 102, a sinter layer 106 is used to attach metallization layer 108 to the semiconductor die 102. A passivation layer 104 is disposed between portions of the sinter layer 106 and the metallization layer 108, as described in more detail, below.

A top-side patterned metal 110, also referred to as a first-side patterned metal, is provided using a patterned top-side metal plating layer, as referenced above. The pattern formed in, or using, the top-side patterned metal 110 may be referred to as a stress-relief pattern. In the example of FIG. 1A, a first portion of the top-side patterned metal 110 is disposed on a portion of the metallization layer 108 connected to a source portion of the semiconductor die 102. The source portion of the semiconductor die 102, a source portion of the metallization layer 108, and corresponding portion of the top-side patterned metal 110 are collectively referred to as a source 112. A second portion of the top-side patterned metal 110 is disposed on a portion of the metallization layer 108 connected to a gate portion of the semiconductor die 102, all of which are collectively referred to as a gate 114.

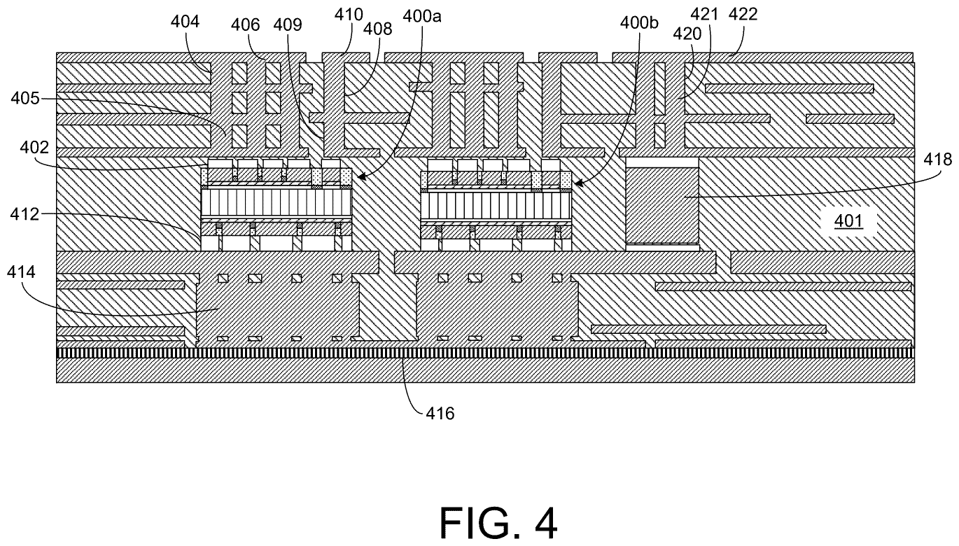

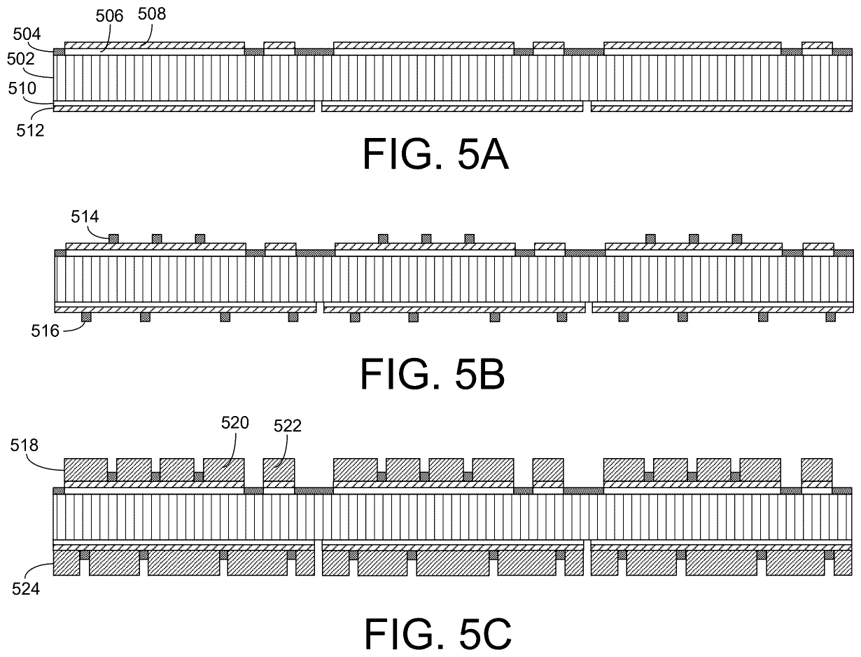

A passivation layer 113, e.g., polyimide passivation layer, is disposed in spaces or openings 111 of the top-side patterned metal 110. As described below, e.g., with respect to FIG. 5B, the passivation layer 113 may have been used as part of a mask used to form the top-side patterned metal 110, along with the passivation layer 104.

Further in FIG. 1A, an encapsulant 115 is illustrated as surrounding and enclosing the top-side patterned metal 110. As shown, the encapsulant 115 is also disposed within the openings 111 of the top-side patterned metal 110. The encapsulant 115 may represent any suitable mold material, e.g., resin or epoxy.

Similar comments as provided above with respect to the top or first side of the semiconductor die 102 apply to an opposed side of the semiconductor die 102, referred to as a second or bottom side of the semiconductor die 102. Specifically, on the bottom side of the semiconductor die 102, a sinter layer 116 is used to attach metallization layer 118 to the semiconductor die 102.

A bottom-side patterned metal 120, also referred to as a second-side patterned metal, provides a patterned bottom-side metal plating layer, as referenced above. Also as above, the pattern formed in, or using, the bottom-side patterned metal 120 may be referred to as a stress-relief pattern. In the example of FIG. 1A, the bottom-side patterned metal 120 is disposed on the metallization layer 118 that is itself connected to a drain portion of the semiconductor die 102, all of which are collectively referred to as a drain 126.

A passivation layer 122 is disposed in spaces or openings 125 of the bottom-side patterned metal 120. As described below, e.g., with respect to FIG. 5B, the passivation layer 122 may have been used as part of a mask used to form the bottom-side patterned metal 120. As further illustrated, encapsulant 124 is disposed within the openings 125.

FIG. 1A thus illustrates that the term patterned metal refers to a metal layer, e.g., a plated metal layer, having openings or spacings formed therein so that the metal layer exhibits a pattern defined by the openings. That is, the top-side patterned metal 110 exhibits a pattern defined by the openings 111, as well as by spacing between the source 112 and the gate 114, while the bottom-side patterned metal 120 exhibits a pattern defined by the openings 125.

The patterned metals 110, 120 thus provide for relief of mechanical stress on the semiconductor die 102, making the semiconductor die 102 less likely to warp or break, e.g., when handled by a PCB provider during an embedding process(es). For example, a total quantity or mass of the top-side patterned metal 110 and the bottom-side patterned metal 120 may be the same or almost the same, thereby providing an equilibrium with respect to forces applied to the semiconductor device 100a during handling thereof. In particular, as referenced above and described in more detail, below, the top-side patterned metal 110 (and the encapsulant 115) and the bottom-side patterned metal 120 (and the encapsulant 124) may both be exposed to a grinding process that reduces a height of both of the top-side patterned metal 110 and the bottom-side patterned metal 120 to a desired height. Such grinding process(es) may further ensure a uniform height across an entirety of the top-side patterned metal 110 and of the bottom-side patterned metal 120.

Because of the equilibrium of opposed forces applied by the top-side patterned metal 110 and the bottom-side patterned metal 120 during wafer handling, a thickness of the patterned metals 110, 120 may be increased relative to existing metal layers formed on a semiconductor die, without causing increased incidents of breakage or warpage. For example, a thickness of the metal layers 110, 120 may be 10 microns, 50 microns, 100 microns, or more. As a result, and as illustrated in more detail, below, drilling of vias through the patterned metal layers 110, 120 to form electrical connections may be performed quickly and inexpensively, without concern for overdrilling that may cause damage to the semiconductor die 102.

In the example of FIG. 1A, the semiconductor device 100a represents a transistor, which may be any suitable transistor made from any suitable material, such as a Silicon (Si), Si Carbide (SiC), or Gallium Nitride (GaN) transistor. Of course, these are just examples, and various types of semiconductor devices, e.g., diodes, may be included, or combinations of devices (e.g., transistors, diodes) may be included.

For example, the semiconductor device 100a may represent various types of power transistors, such as insulated-gate bipolar transistors (IGBTs), power metal-oxide-semiconductor field effect transistors (MOSFETs), and so forth. Electrical interconnections within a high-power semiconductor device package can include, for example, bond wires, conductive spacers, metal and insulating built up layers, and conductive clips.

Although sinter, e.g., Ag sinter, is mentioned above, other die attach materials or techniques may be used, e.g., solder. Any suitable metal may be used for metallization layers, e.g., alloys of Titanium, nickel, and/or silver. Copper plating provides on example of material and techniques that may be used to form the top-side and bottom-side patterned metals 110, 120, but other suitable materials and techniques may be used, as well.

FIG. 1B is a top view of a semiconductor device 127 that may use double-sided plating as described with respect to FIG. 1A. In the example of FIG. 1B, the semiconductor device 127 is illustrated as including a source contact 128, as well as additional contacts 130, 132, 134, which may represent, e.g., a gate contact, a Kelvin sensor contact, or other contacts. FIG. 1B is not limiting with respect to any type of semiconductor device that may benefit from described techniques. Rather, the semiconductor device 127 of FIG. 1B is merely intended to illustrate an example of contacts that may be formed on a topside of a semiconductor device, so as to describe example aspects of topside patterned metals that may be formed with respect to such contacts.

For example, it will be appreciated from the description of FIG. 1A that the top-side patterned metal 110 may be formed on, or with respect to, the contacts 128, 130, 132, 134, to provide the various benefits and advantages described above. For example, the top-side patterned metal may be formed over some or all of each of the contacts 128, 130, 132, 134. The top-side patterned metal 110 may also extend beyond a perimeter of one or more of the contacts 128, 130, 132, 134. As described with respect to FIG. 1A, suitable mold material may be provided within any recesses of the topside patterned metal 110 as disposed on the semiconductor device 127, including between the various contacts 128, 130, 132, 134, in order to provide mechanical stress relief and electrical isolation. The patterning of any such top-side patterned metal and associated recesses may be determined, e.g., using a suitable simulation tool capable of determining metal patterns that reduce warpage or otherwise relieve mechanical stress that would otherwise be applied to the semiconductor device 127.

FIG. 1C is a bottom view of a semiconductor device 135 with double-sided plating. In the example of FIG. 1C, bottom-side patterned metal 136 is formed on the semiconductor device 135. Spaces 138 are formed between portions of the bottom-side patterned metal 136, and may be filled with a suitable passivation layer and/or encapsulant (not shown separately in FIG. 1C).

It will be appreciated that FIG. 1C should not be understood to necessarily correspond to the top view of the example semiconductor device 127 of FIG. 1B. Rather, FIG. 1C merely illustrates that virtually any desired pattern of patterned metal and associated spacings may be defined, and that such pattern(s) may be selected to compensate for mechanical forces imposed by a corresponding top-side metal pattern selected for implementation on a top side of a corresponding semiconductor device. Such compensation may depend on multiple factors, such as, e.g., a material of the underlying semiconductor die, a size of the semiconductor die, a thickness of the semiconductor die, and/or properties of individual devices (e.g., transistors, diodes) formed in the semiconductor die.

Thus, FIGS. 1A-1C generally illustrate examples of a semiconductor device having a first side and a second side opposed to the first side, a first metallization layer disposed on the first side, and a first metal layer formed on the first metallization layer. The first metal layer includes a first pattern defined by a first space, the first space containing a first non-conducting material formed on the first metallization layer. A second metallization layer is disposed on the second side, and a second metal layer is formed on the second metallization layer. The second metal layer includes a second pattern defined by a second space, and the second space contains a second non-conducting material formed on the second metallization layer. A first encapsulant may be disposed in the first space on the first non-conducting material and a second encapsulant may be disposed in the second space on the second non-conducting material. The first encapsulant and the first metal layer may be ground to a first uniform height and the second encapsulant and the second metal layer may be ground to a second uniform height, where the first uniform height and the second uniform height may be equal. The first space of the first metal layer may include multiple first spaces defining first stress relief lines, and the second space may include multiple second spaces defining second stress relief lines (e.g., stress relief lines 138 of FIG. 1C).

The second pattern may be based on the first pattern to provide mechanical stress relief for the semiconductor device. For example, a simulation tool may be used to model the first and second patterns relative to underlying contact pads and to one another, and to optimize the first and second patterns to minimize warpage of an underlying semiconductor die.

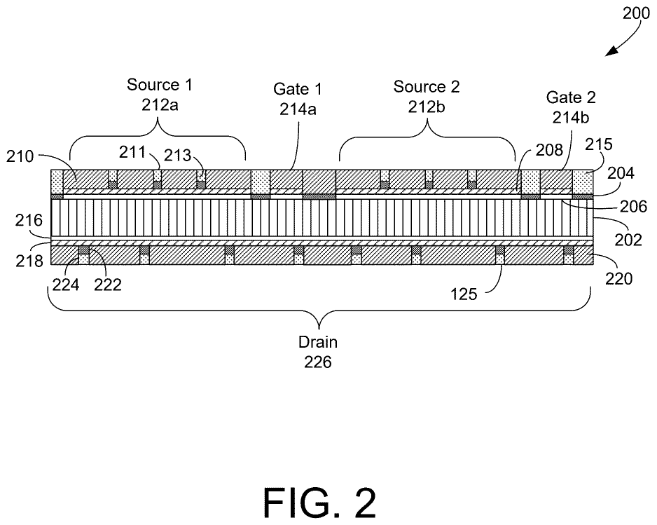

FIG. 2 is a side view of a multi-device semiconductor device 200 with double-sided plating. In the example of FIG. 2, as in FIG. 1A, a semiconductor die 202 is illustrated as having a first or top side in an upper portion of the figure, and a second or bottom side on a lower portion of the figure. On the top side of the semiconductor die 202, a sinter layer 206 is used to attach metallization layer 208 to the semiconductor die 202. A passivation layer 204 is disposed between portions of the sinter layer 206 and the metallization layer 208, as described in more detail, below.

A top-side patterned metal 210, also referred to as a first-side patterned metal, is provided using a patterned top-side metal plating layer, as in the example of FIG. 1A. A first portion of the top-side patterned metal 210 is disposed on a portion of the metallization layer 208 connected to a first source portion of the semiconductor die 202. The first source portion of the semiconductor die 202, a first source portion of the metallization layer 208, and corresponding portion of the top-side patterned metal 210 are collectively referred to as a first source 212a. A second portion of the top-side patterned metal 210 is disposed on a portion of the metallization layer 208 connected to a first gate portion of the semiconductor die 202, all of which are collectively referred to as a first gate 214a.

A third portion of the top-side patterned metal 210 is disposed on a portion of the metallization layer 208 connected to a second source portion of the semiconductor die 202. The second source portion of the semiconductor die 202, a second source portion of the metallization layer 208, and corresponding portion of the top-side patterned metal 210 are collectively referred to as a second source 212b. A fourth portion of the top-side patterned metal 210 is disposed on a portion of the metallization layer 208 connected to a second gate portion of the semiconductor die 202, all of which are collectively referred to as a second gate 214b.

A passivation layer 213, e.g., polyimide passivation layer, is disposed in spaces or openings 211 of the top-side patterned metal 210. As described below, e.g., with respect to FIG. 5B, the passivation layer 213 may have been used as part of a mask used to form the top-side patterned metal 210, along with the passivation layer 204.

Further in FIG. 2, an encapsulant 215 is illustrated as surrounding and enclosing the top-side patterned metal 210. As shown, the encapsulant 215 is also disposed within the openings 211 of the top-side patterned metal 210. The encapsulant 215 may represent any suitable mold material, e.g., resin or epoxy.

Similar comments as provided above with respect to the top or first side of the semiconductor die 202 apply to an opposed side of the semiconductor die 202, referred to as a second or bottom side of the semiconductor die 202. Specifically, on the bottom side of the semiconductor die 202, a sinter layer 216 is used to attach metallization layer 218 to the semiconductor die 202.

A bottom-side patterned metal 220, also referred to as a second-side patterned metal, provides a patterned bottom-side metal plating layer, as referenced above. In the example of FIG. 2, the bottom-side patterned metal 220 is disposed on the metallization layer 218 that is itself connected to a drain portion of the semiconductor die 202, all of which are collectively referred to as a drain 226.

A passivation layer 222 is disposed in spaces or openings 225 of the bottom-side patterned metal 220. As described below, e.g., with respect to FIG. 5B, the passivation layer 222 may have been used as part of a mask used to form the bottom-side patterned metal 220. As further illustrated, encapsulant 224 is disposed within the openings 225.

FIG. 2 thus illustrates that multiple devices and/or multiple chips may be included in a single, larger semiconductor device. FIG. 2 is non-limiting, and more than two devices/chips may be included. FIG. 2 shares many or all of the advantages and features described with respect to FIG. 1A. For example, the patterned metals 210, 220 provide for relief of mechanical stress on the semiconductor die 202, making the semiconductor die 202 less likely to warp or break. The top-side patterned metal 210 (and the encapsulant 215) and the bottom-side patterned metal 220 (and the encapsulant 224) may both be exposed to a grinding process that reduces a height of both of the top-side patterned metal 210 and the bottom-side patterned metal 220 to a desired height. Such grinding process(es) may further ensure a uniform height across an entirety of the top-side patterned metal 210 and of the bottom-side patterned metal 220.

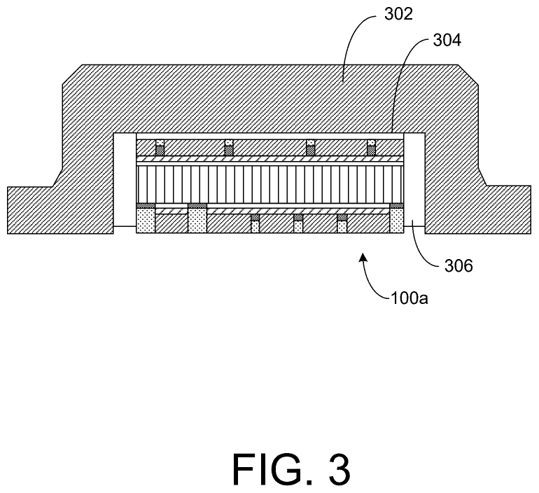

FIG. 3 is a side view of a first example semiconductor device package that includes the semiconductor device of FIG. 1A. In FIG. 3, the semiconductor device 100a is attached to a substrate 302 by a connecting layer 304, e.g., a sinter layer. Encapsulant 306 is provided around the semiconductor device 100a and provides, e.g., protection and isolation, while fixing the semiconductor device 100a to the substrate 302.

The substrate 302 may represent any suitable mounting surface or mounting member in which the semiconductor device 100a may be positioned. For example, the substrate 302 may represent a leadframe, such as a metal leadframe (e.g., a copper leadframe).

The simplified example of FIG. 3 illustrates the substrate 302 as a single material, but the substrate 302 may also be composed of multiple materials. For example, the substrate 302 may include multiple layers in a direct bonded metal (DBM) or direct bonded copper (DBC) structure, in which a dielectric material is sandwiched between two metal (e.g., copper or aluminum) material(s). The substrate 302 may be part of a larger printed circuit board (PCB) and panel assembly.

The substrate 302 may be implemented as, or in conjunction with, a lead frame that is used to provide external electrical connections to the high-power semiconductor device 100a. For example, some of the high-power assemblies described herein can operate at voltages in a range of about 200 V to about 800 V. Such high-power chip assemblies, encapsulated as embedded semiconductor device modules, can be used in various applications, including electric vehicles (EVs), hybrid electric vehicles (HEVs), and industrial applications.

FIG. 4 is a side view of a second example semiconductor device package that includes the semiconductor device of FIG. 1A. In the device package of FIG. 4, a semiconductor device 400a and a semiconductor device 400b correspond generally to the semiconductor device 100a of FIG. 1A. Further description of the device package of FIG. 4 is primarily provided with respect to connections to, and packaging of, the semiconductor device 400a, but it will be understood that similar descriptions apply to the semiconductor device 400b and its corresponding connections and packaging, as well.

As shown, a source region of the semiconductor device 400a is attached by a portion of a sinter layer 402 to a plurality of source contacts 405 established using source vias 404, thereby defining a source connection 406. Similarly, a gate region of the semiconductor device 400a is attached by a portion of the sinter layer 402 to a plurality of gate contacts 409 established using gate vias 408, thereby defining a gate connection 410.

At an opposed side of the semiconductor device 400a, the semiconductor device 400a is attached by a sinter layer 412 to drain contact(s) 414. In the example of FIG. 4, the semiconductor device 400a and the semiconductor device 400b are connected using a metal connector 418, through drain vias 420 having drain contacts 421 disposed therein, to a drain connection 422. Other techniques for establishing a drain connection(s) may be used, as well.

Further in FIG. 4, the semiconductor devices 400a, 400b are disposed and encased in a core layer 401. The core layer 401 may include, e.g., any suitable material or composite material used for semiconductor packaging. For example, the core layer 401 may be formed from FR-4 (Flame Retardant 4), a composite material of woven fiberglass or other reinforcing material, impregnated with an epoxy resin. The core layer 401 may be prepared with cutouts in which to place the semiconductor devices 400a, 400b, and the metal connector 418 may provide a mechanical as well as electrical connection to stabilize the overall semiconductor package of FIG. 4. A thermal pre-preg layer 416 is positioned across a bottom of the core layer 401 and the semiconductor devices 400a, 400b. Pre-preg layer 416 generally refers to a reinforcing material, such as fiberglass or other fabrics, impregnated with a partially cured resin, such as epoxy, which provides thermal and mechanical stability.

FIGS. 5A-5C illustrate example operations for forming a semiconductor device with double-sided plating (1102 in FIG. 11). In FIG. 5A, a semiconductor die 502 is illustrated as having a sinter layer 506 disposed on a topside thereof, which is used to attach metallization layer 508 to the semiconductor die 502. A passivation layer 504 is disposed between portions of the sinter layer 106 and the metallization layer 108, to divide and define future source and gate contact regions. On an opposed (bottom) side of the semiconductor die 502, a sinter layer 510 is used to attach metallization layer 512 to the semiconductor die 502.

In FIG. 5B, a polyimide layer mask 514 is disposed on a first or top surface of the semiconductor die 502. A polyimide layer mask 516 is disposed on a second or bottom surface of the semiconductor die 502.

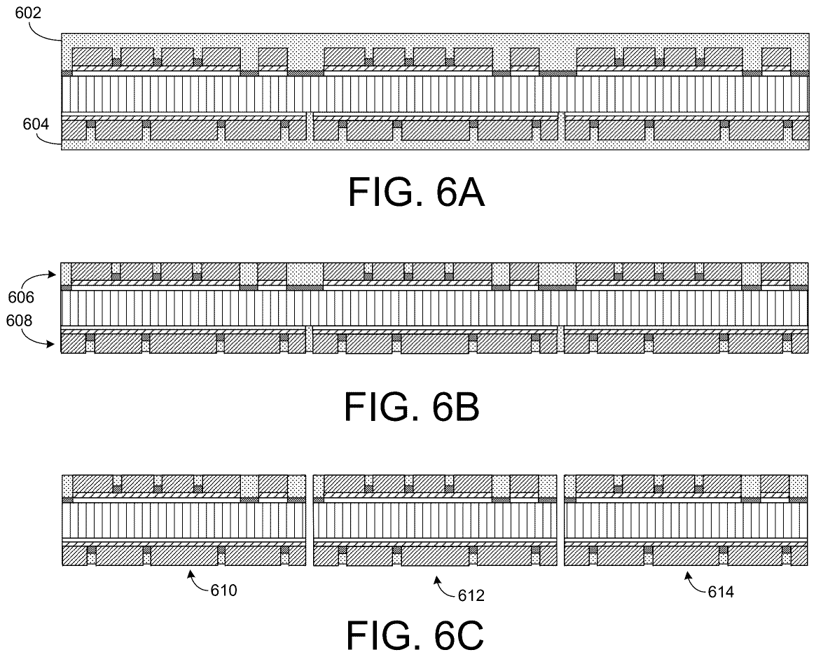

In FIG. 5C, a top-side patterned metal 518 is formed on the first or top surface of the semiconductor die 502, e.g., on the metallization layer 508, where the polyimide layer mask 514 is not present. Accordingly, and as referenced above and described in more detail, below (e.g., with respect to FIGS. 6A-6C), a source contact portion 520 and a gat contact portion 522 for a single transistor device may be defined. Further, a bottom-side patterned metal 524 is formed on the second or bottom surface of the semiconductor die 502, e.g., on the metallization layer 512, where the polyimide layer mask 516 is not present, which provides a drain contact portion for a transistor device.

For example, the patterned metals 518, 524 may be formed using plating techniques, e.g., Cu plating. Plating may be performed using electroless or galvanic (electroplating) techniques. Plating may be performed simultaneously on both surfaces (top and bottom) of the semiconductor die 502, so that the patterned metals 518, 524 are formed at approximately the same rate and have approximately the same thickness.

FIGS. 6A-6C illustrate further example operations for forming a semiconductor device with double-sided plating (1104 in FIG. 11). In FIG. 6A, a top-side encapsulant 602 is provided over and around an entire top surface, and a bottom-side encapsulant 604 is provided over and around an entire bottom surface. In FIG. 6B, top-side and bottom-side grinding operations are performed, resulting in a top layer 606 and a bottom layer 608 in which all patterned metals and surrounding encapsulant materials are ground to a consistent, uniform height.

Then, in FIG. 6C, singulation or dicing is performed to provide three separate, singulated devices 610, 612, 614. In the example of FIG. 6C, singulation is performed to provide devices 610, 612, 614 that are analogous to the single chip device of FIG. 1A. In other examples, singulation may be performed to provide the multi-chip device of FIG. 2 (e.g., singulating only the device 610 as a single-chip device, and leaving the remaining devices 612, 614 as a multi-chip device).

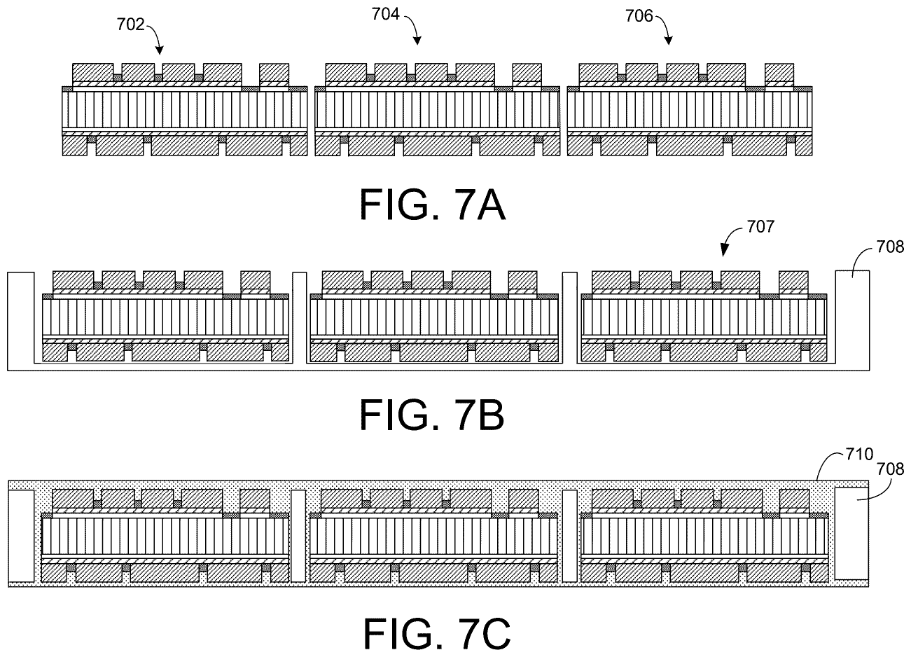

FIGS. 7A-7C illustrate example alternate operations for forming a semiconductor device with double-sided plating (1106 in FIG. 11). More specifically, FIGS. 7A-7C follow the operations of FIGS. 5A-5C and provide alternate operations for the operations of FIGS. 6A-6C, which provide sidewall protection of resulting chips, e.g., against conductive anodic filaments (CAFs).

In FIG. 7A, following the operation of FIG. 5C, singulation is performed to define devices 702, 704, 706. In FIG. 7B, the singulated devices are disposed within cavities 707 of an EMC core 708. As shown, the cavities 707 are of sufficient size to provide clearance to receive an encapsulant. Then, in FIG. 7C, encapsulant 710 is disposed around the devices within the EMC core 708, and onto the core 708.

The EMC core 708 may be provided as a waffle tray in which various cavities are defined to receive singulated devices. For example, an original wafer may be of a certain size and shape, e.g., a six inch circular wafer. Upon singulation and depositing into a core such as the core 708, a new panel size and shape may effectively be defined that is determined by the size/shape of the core. In this way, a molded panel is provided.

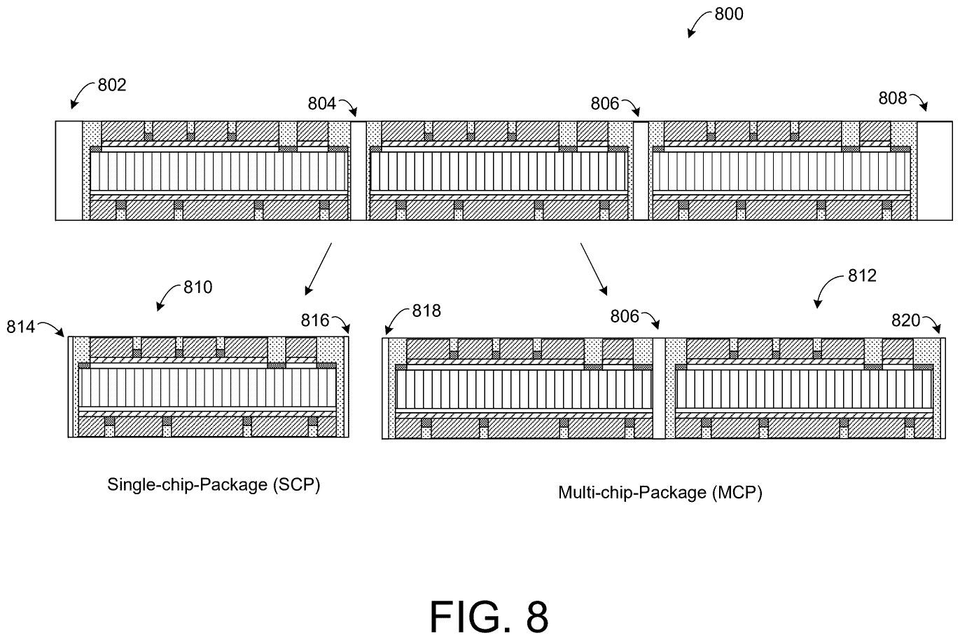

FIG. 8 illustrates example grinding and dicing of a result of the operations of FIG. 7C (1108, 1110 in FIG. 11). In FIG. 8, grinding of the encapsulated devices and EMC core 708 of FIG. 7C results in a structure 800 similar to that of FIG. 6B, but with sidewalls 802, 804, 806, 808 remaining from the EMC core 708.

As also illustrated in FIG. 8, subsequent singulation(s) (e.g., dicing or sawing) may be performed to obtain a single chip package 810 and/or a multi-chip package 812. As shown, the single chip package 810 is similar to the single chip package of FIG. 1A, but with sawed/diced sidewalls 814, 816. The multi-chip package 812 is similar to the multi-chip package of FIG. 2, but with sawed/diced sidewalls 818, 820, as well as remaining sidewall (core portion) 806.

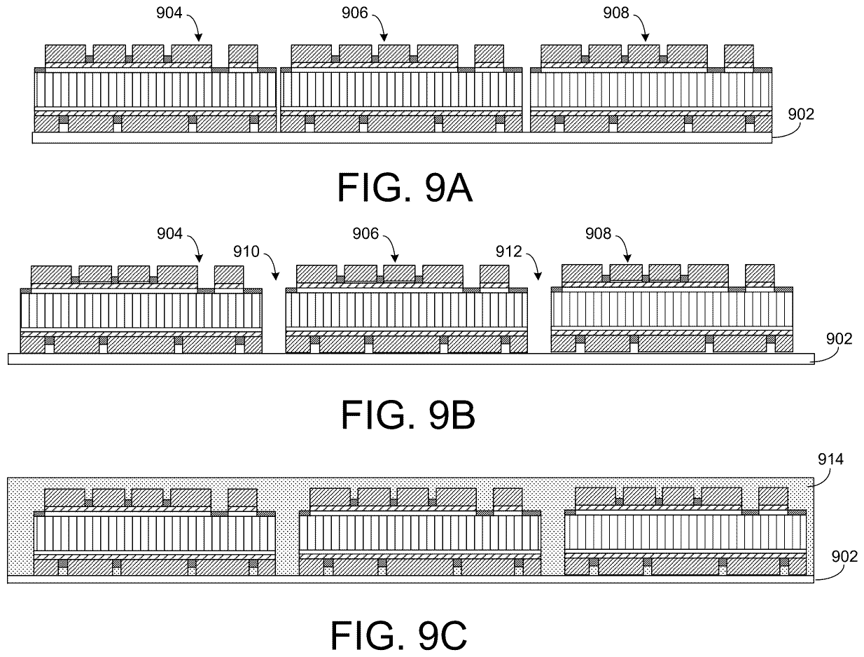

FIGS. 9A-9C illustrate example alternate fourth, fifth, and sixth operations for forming a semiconductor device with double-sided plating (1112 in FIG. 11). In FIG. 9A, somewhat similar to FIG. 7A, singulation is performed to obtain semiconductor devices 904, 906, 908. In FIG. 9A, however, the semiconductor devices 904, 906, 908 are illustrated as being positioned on wafer transfer tape 902.

Wafer transfer tape 902 may typically be used to provide support during transport and handling operations. For example, the wafer transfer tape 902 may be UV-sensitive, so that exposure to ultraviolet light reduces an adhesion of the wafer transfer tape 902 for subsequent handling (e.g., pick and place) of each individual semiconductor die/device on the wafer transfer tape 902.

In FIG. 9B, matrix expansion is implemented to create spaces 910, 912 between the individual semiconductor devices 904, 906, 908, as shown. In general, such matrix expansion refers generally to a process in which such increased spacing is created to facilitate easier handling and to prevent die damage during further processing. For example, an expansion machine may be used to expand the transfer tape uniformly in both X and Y directions, which spreads the mounted die apart. Such an approach, e.g., reduces the risk of die edge chipping or cracking, and makes die singulation and pick-and-place operations more reliable.

In FIG. 9C, encapsulant 914 is added. Subsequently, following removal of the transfer tape 902, grinding and further singulation may be performed, as shown and described with respect to FIG. 8 (1108, 1110 in FIG. 11).

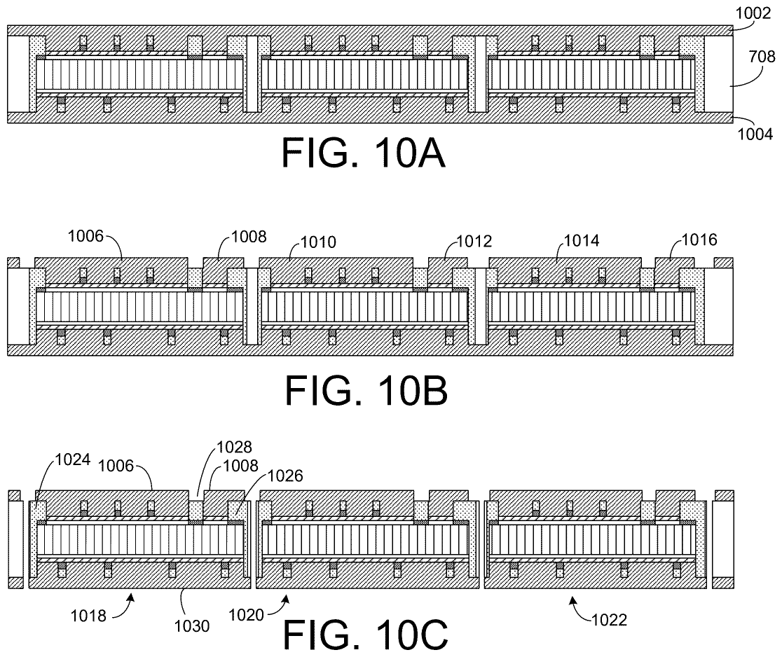

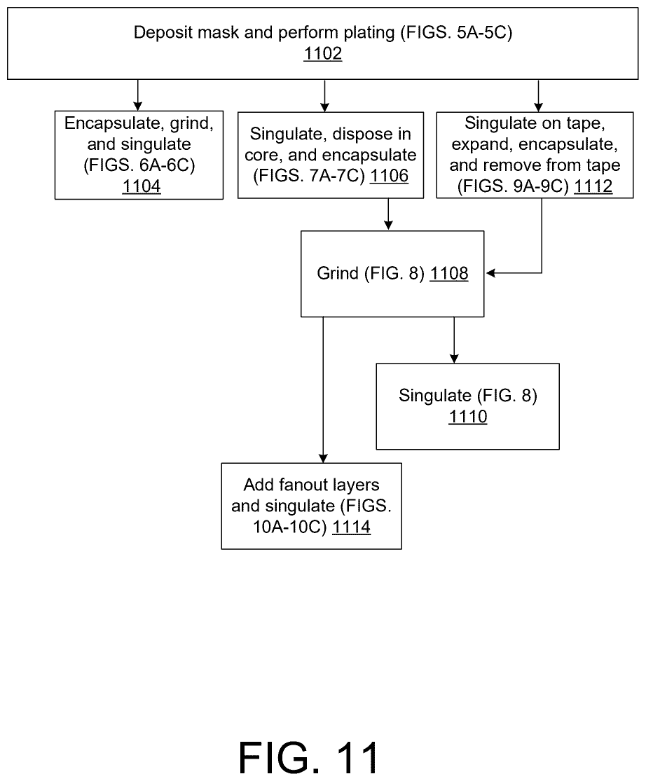

FIGS. 10A-10C illustrate example operations for forming a semiconductor device with double-sided plating and sidewall protection, with fanout layers (1114 in FIG. 11). In FIG. 10A, the structure 800 of FIG. 8 undergoes further galvanic plating to add a top fanout plating layer 1002 and a bottom fanout plating layer 1004.

In FIG. 10B, photolithography and etching operations may be performed to define separate source contacts 1006, 1010, 1014 and gate contacts 1008, 1012, 1016. In FIG. 10C, singulation is performed to provide individual devices 1018, 1020, 1022.

As shown, each singulated device includes protective EMC core sidewalls 1024, 1026. As referenced above, such sidewalls provide additional stability and reliability during handling, while also providing protection against CAFs that may lead to short circuits or other device failures.

As may be further observed with respect to, e.g., the device 1018, the fanout layers 1006 and 1008 provide easy and reliable source and gate connections, respectively, while space 1028, together with the fanout layers 1006, 1008 provide the type of top-side patterned metal layer described above, e.g., with respect to FIG. 1A.

In FIG. 10C, the bottom-side metal layer 1030, providing an easy and reliable drain connection, is illustrated as a uniform fanout layer. That is, the bottom-side metal layer 1030 is not patterned, but rather is uniform. Nonetheless, the bottom-side metal layer 1030 may provide the type of stability and prevention of warpage/breakage described above, e.g., with respect to FIG. 1A, and in conjunction with the top-side patterned metal 1006, 1008. In alternate implementations, the bottom-side fanout metal layer 1030 may be patterned in a similar manner to that described, e.g., with respect to FIG. 1A and/or FIG. 1C.

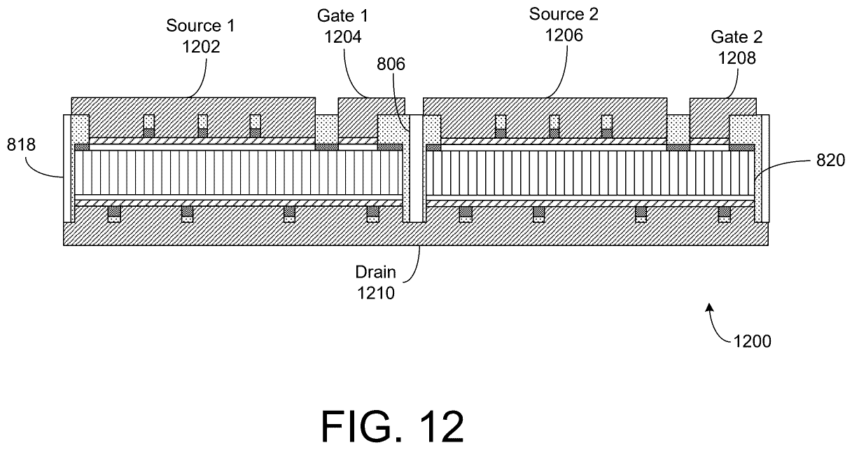

FIG. 12 is an example multi-chip semiconductor device 1200 with double-sided plating and sidewall protection, with fanout layers. The device 120 may be formed after the operations of FIG. 10B. The device 1200 is conceptually similar to the multi-chip device 812 of FIG. 8, but including fanout layers. The device 1200 is also conceptually similar to the device 200 of FIG. 2, but with sidewall protection and fanout layers.

More specifically, as shown, the device 1200 includes sidewalls 806, 818, 820 as described with respect to FIG. 8. The device 1200 further includes sources 1202, 1206 with fanout layers, and corresponding gates 1204, 1208, also with fanout layers. A drain 1210 provides a common drain for the device (similar to the common drain 1018 of FIG. 10C), with a fanout layer.

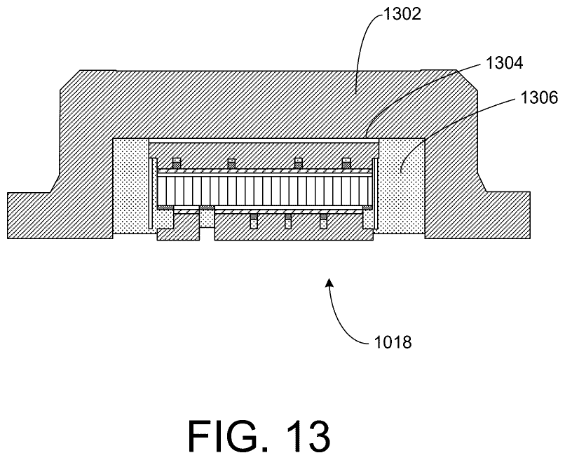

FIG. 13 is a first example semiconductor device package for a semiconductor device with double-sided plating and sidewall protection, with fanout layers. Specifically, FIG. 13 is described with respect to the example device 1018 of FIG. 10C.

In FIG. 13, the semiconductor device 1018 is attached to a substrate 1302 by a connecting layer 1304, e.g., a sinter layer. Encapsulant 1306 is provided around the semiconductor device 1018 and provides, e.g., protection and isolation.

The substrate 1302 may represent any suitable mounting surface or mounting member in which the semiconductor device 1018 may be positioned. For example, the substrate 1302 may represent a leadframe, such as a metal leadframe (e.g., a copper leadframe).

The simplified example of FIG. 13 illustrates the substrate 1302 as a single material, but the substrate 1302 may also be composed of multiple materials. For example, the substrate 1302 may include multiple layers in a DBM, e.g., DBC structure. The substrate 1302 may be part of a larger printed circuit board (PCB) and panel assembly. The substrate 1302 may be implemented as, or in conjunction with, a lead frame that is used to provide external electrical connections to the high-power semiconductor device 1018.

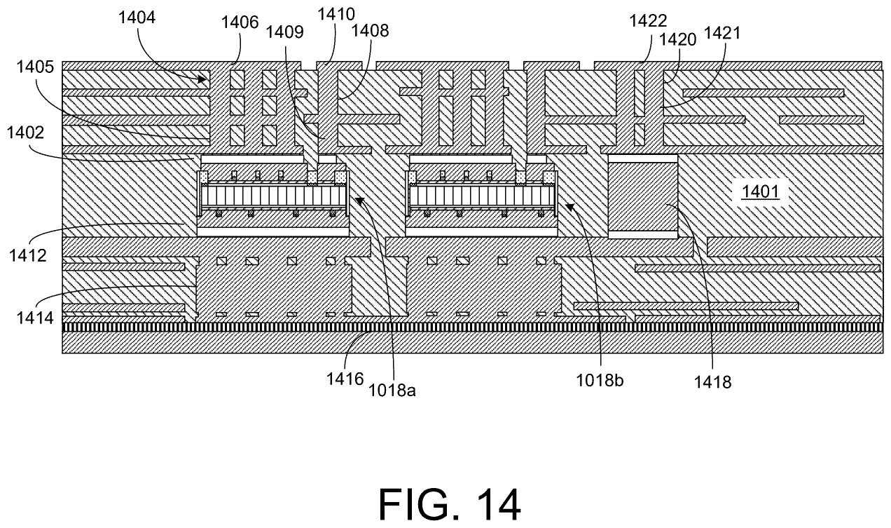

FIG. 14 is a second example semiconductor device package for a semiconductor device with double-sided plating and sidewall protection, with fanout layers. In the device package of FIG. 14, a semiconductor device 1018a and a semiconductor device 1018b correspond generally to the semiconductor device 1018 of FIG. 10C. Further description of the device package of FIG. 14 is primarily provided with respect to connections to, and packaging of, the semiconductor device 1018a, but it will be understood that similar descriptions apply to the semiconductor device 1018b and its corresponding connections and packaging, as well.

As shown, a source region of the semiconductor device 1018a is attached by a portion of a sinter layer 1402 to a plurality of source contacts 1405 established using source vias 1404, thereby defining a source connection 1406. Similarly, a gate region of the semiconductor device 1018a is attached by a portion of the sinter layer 1402 to a plurality of gate contacts 1409 established using gate vias 1408, thereby defining a gate connection 1410.

At an opposed side of the semiconductor device 1018a, the semiconductor device 1018a is attached by a sinter layer 1412 to drain contact(s) 1414. In the example of FIG. 14, the semiconductor device 1018a and the semiconductor device 1018b are connected using a metal connector 1418, through drain vias 1420 having drain contacts 1421 disposed therein, to a drain connection 1422. Other techniques for establishing a drain connection(s) may be used, as well.

Further in FIG. 14, the semiconductor devices 1018a, 1018b are disposed and encased in a core layer 1401. The core layer 1401 may include, e.g., any suitable material or composite material used for semiconductor packaging. For example, the core layer 1401 may be formed from FR-4. The core layer 1401 may be prepared with cutouts in which to place the semiconductor devices 1018a, 1018b and the metal connector 1418 may provide a mechanical as well as electrical connection to stabilize the overall semiconductor package of FIG. 14. A thermal pre-preg layer 1416 is positioned across a bottom of the core layer 1401 and the semiconductor devices 1018a, 1018b.

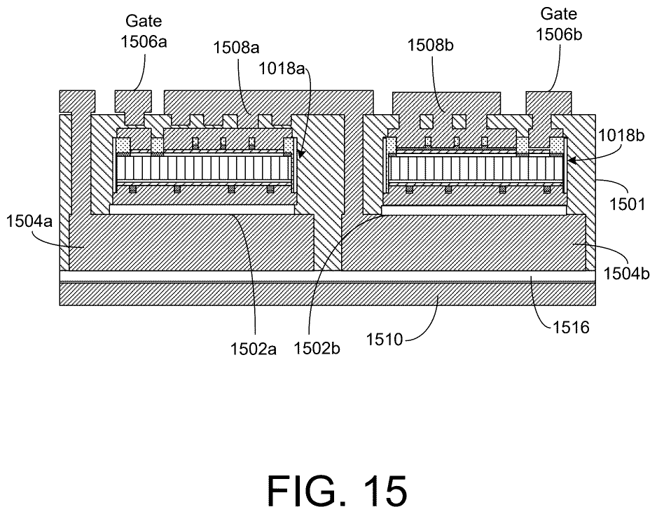

FIG. 15 is a third example semiconductor device package for a semiconductor device with double-sided plating and sidewall protection, with fanout layers. Similar to FIG. 14, FIG. 15 provides an example of packaging devices 1018a, 1018b corresponding to the device 1018 of FIG. 10C.

In FIG. 15, sinter layers 1502a, 1502b attach the devices 1018a, 1018b, respectively, to leadframes 1504a, 1504b, also respectively, the leadframes 1504a, 1504b providing drain connections for the devices 1018a, 1018b. The device 1018a is provided with a gate connection 1506a, while the device 1018b is provided with a gate connection 1506b. The device 1018a is provided with a source connection 1508a, while the device 1018b is provided with a source connection 1508b.

Further in FIG. 15, the semiconductor devices 1018a, 1018b are disposed and encased in a core layer 1501. The core layer 1501 may include, e.g., any suitable material or composite material used for semiconductor packaging. For example, the core layer 1501 may be formed from FR-4. A thermal pre-preg layer 1516 is positioned across a bottom of the core layer 1501 and the semiconductor devices 1018a, 1018b, and is disposed on a metal layer 1510.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a DBM substrate can be formed by bonding one or more metal layers (e.g., a first metal layer, second metal layer) to an insulating layer. In some implementations, one or more of the metal layers can be bonded to the insulating layer using, for example, a high-temperature process.

In some implementations, a DBM substrate can include an insulating layer disposed between the first metal layer and the second metal layer. The insulating layer can be, for example, a ceramic layer. In some implementations, the insulating layer can be or can include, for example, a ceramic material such as alumina (Al₂O₃) or aluminum nitride (AlN).

In some implementations, one or more metal layers can be or can function as a heat sink. In some implementations, the one or more metal layers can be coupled to a heat sink. In some implementations, at least a portion of the one or more metal layers can be exposed through a molding material.

In some implementations, the one or more metal layers can be or can include a patterned metal layer including one or more electrically conductive traces. In some implementations, the one or more metal layers can be or can include a patterned layer configured to form one or more electrical circuits, one or more conductive blind and/or through vias, and/or so forth.

In some implementations, the DBM substrate can be, or can include, a direct bonded copper (DBC) substrate. In some implementations, such as in DBC substrate implementations, the metal layers of the DBC may be, or may include, a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor dies may be also connected to lead frame posts by electrical connections such as wirebonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

In some implementations, a mold material (e.g., molding material or compound, an encapsulation material) can be or can include a non-conducting layer/material.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer)

In some implementations, a module (e.g., a package including a semiconductor device) can be included in another module. The module can be referred to as a package. For example, one or more modules can be one or more sub modules included within another module. In other words, a first module can be included as a sub module within a second module.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor device package, comprising:
a semiconductor device having a first side and a second side opposed to the first side;
a first metallization layer disposed on the first side;
a first metal layer formed on the first metallization layer, the first metal layer including a first pattern defined by a first space, the first space including a first non-conducting material formed on the first metallization layer;
a second metallization layer disposed on the second side; and
a second metal layer formed on the second metallization layer.

2. The semiconductor device package of claim 1, wherein the second metal layer includes a second pattern defined by a second space, the second space including a second non-conducting material formed on the second metallization layer.

3. The semiconductor device package of claim 2, further comprising a first encapsulant disposed in the first space on the first non-conducting material and a second encapsulant disposed in the second space on the second non-conducting material.

4. The semiconductor device package of claim 3, wherein the first encapsulant and the first metal layer are ground to a first uniform height and the second encapsulant and the second metal layer are ground to a second uniform height.

5. The semiconductor device package of claim 4, wherein the first uniform height and the second uniform height are approximately equal.

6. The semiconductor device package of claim 2, wherein the first space includes multiple first spaces defining first stress relief lines, and the second space includes multiple second spaces defining second stress relief lines.

7. The semiconductor device package of claim 2, wherein the second pattern is based on the first pattern to provide mechanical stress relief for the semiconductor device.

8. The semiconductor device package of claim 1, wherein the first space includes an encapsulant, and the first metal layer and the encapsulant are ground to a uniform height.

9. The semiconductor device package of claim 1, further comprising:
an insulating sidewall disposed on a side of the semiconductor device and extending from the first metal layer to the second metal layer.

10. The semiconductor device package of claim 1, further comprising:
a fanout layer disposed on the first metal layer and extending over the first space, and in contact with the first metal layer on either side of the first space.

11. A package for an embedded semiconductor device, the package comprising:
a substrate;
a semiconductor device disposed on the substrate, the semiconductor device having a first side and a second side opposed to the first side;
a first metallization layer disposed on the first side;
a first metal layer formed on the first metallization layer and including a first stress-relief pattern defined by a first metal layer portion and a second metal layer portion with a first space therebetween, the first space including a first non-conducting material formed on the first metallization layer;
a second metallization layer disposed on the second side;
a second metal layer formed on the second metallization layer; and
an encapsulant fixing the semiconductor device, the first metal layer, and the second metal layer to the substrate.

12. The package of claim 11, wherein the second metal layer includes a second stress-relief pattern defined by a second space, the second space including a second non-conducting material formed on the second metallization layer.

13. The package of claim 12, wherein the second pattern is based on the first stress-relief pattern to provide mechanical stress relief for the semiconductor device.

14. The package of claim 12, wherein the first space includes multiple first spaces defining first stress relief lines, and the second space includes multiple second spaces defining second stress relief lines.

15. The package of claim 11, further comprising:
an insulating sidewall disposed on a side of the semiconductor device and extending from the first metal layer to the second metal layer.

16. A method of forming a semiconductor device package, comprising:
forming a first metallization layer on a first side of a semiconductor device;
forming a second metallization layer on a second side of the semiconductor device that is opposed to the first side;
forming a first metal layer on the first metallization layer, the first metal layer including a first pattern defined by a first space;
forming a first non-conducting material in the first space and on the first metallization layer; and
forming a second metal layer on the second metallization layer.

17. The method of claim 16, further comprising:
forming the second metal layer with a second pattern defined by a second space, the second space including a second non-conducting material formed on the second metallization layer.

18. The method of claim 17, further comprising:
forming the second pattern based on the first pattern to provide mechanical stress relief for the semiconductor device.

19. The method of claim 17, further comprising:
forming a first encapsulant disposed in the first space on the first non-conducting material and a second encapsulant disposed in the second space on the second non-conducting material.

20. The method of claim 16, further comprising:
forming an insulating sidewall disposed on a side of the semiconductor device and extending from the first metal layer to the second metal layer.
